(19) United States
(12) Patent Application Publication
(10) Pub. No.: US 2025/0164578 A1
(43) Pub. Date: May 22, 2025

(54) METHOD FOR TESTING A WIRING OF AN ELECTRICAL INSTALLATION

(71) Applicant: OMICRON electronics GmbH, Klaus (AT)

(72) Inventor: Josef Schmidbauer, Salzburg (AT)

(21) Appl. No.: 18/942,950

(22) Filed: Nov. 11, 2024

(30) Foreign Application Priority Data
Nov. 17, 2023 (EP) 23210639.3

(51) Int. Cl. G01R 31/55

(52) U.S. Cl. CPC G01R 31/55

(57) ABSTRACT

The present invention relates to a method for testing wiring of an electrical installation having multiple circuits. In the method, multiple test signals are generated. Each of the multiple test signals has a combination of predefined harmonics having at least one higher harmonic, wherein the amplitude and/or phase of the at least one higher harmonic of the multiple test signals are different. The multiple test signals are injected into multiple first connections, which are assigned to the multiple circuits, at a first point of the electrical installation.

The present application claims priority to EP Application Serial No. 23210639.3, filed Nov. 17, 2023, which is hereby incorporated herein by reference in its entirety.

### FIELD OF THE INVENTION

The present invention relates to a method for testing wiring of an electrical installation, in particular for testing wiring of an electrical installation having multiple circuits, for example a power engineering electrical installation in for example a substation or a power plant.

### BACKGROUND

Wiring errors may occur when installing, repairing or extending an electrical installation, for example in a substation or a power plant. Particularly in installations having multiple circuits and/or multiple phases, for example installations for three-phase AC current, conductors may be mixed up; for example two outer conductors may be mixed up, or an outer conductor may be mixed up with the neutral conductor. Furthermore, a polarity may for example be reversed when connecting a transformer. Therefore, before an electrical installation is commissioned or recommissioned, the wiring is usually tested in order to establish incorrectly connected conductors and reversed polarities.

By way of example, test signals may be injected successively into the individual phases at an injection point and a measurement signal may be acquired at a measuring point remote from said injection point and at which an effect of the test signal should occur if the wiring is correct. If the expected effect of the test signal is not detected at the measuring point, a wiring error could be present. This procedure is comparatively time-consuming since numerous measurements have to be performed in order to check multiple circuits and phases, and the measuring device has to be connected accordingly to the injection point and the measuring point for each measurement. Furthermore, although such a measurement may be used to establish that a wiring error is present, it is not possible to directly establish the type of the wiring error, for example, whether conductors have been mixed up or not connected.

A correct polarity of a current and voltage converter also needs to be checked. An incorrect polarity may for example lead to malfunctioning of a protective relay. In measuring circuits, an incorrect polarity may lead to an apparently opposite current flow direction and thus to incorrect measurement results. For these functions, it is also important to check the correct phase assignment from the transducer to the protective relay or counter.

There are other methods for checking polarity. These may also be used to check the correct phase assignment by proceeding phase by phase and testing whether the expected reaction occurs on the phase to be tested.

For example, a DC voltage test may be performed. In this test, a battery is momentarily connected to one side of the transducer and the momentary deflection of a milliammeter or millivoltmeter connected to the other side is recorded. The DC current that flows during this test could magnetize the transducer. The resulting saturation may lead to malfunctions of the protection system. It is therefore important to demagnetize each current converter tested using this method following the test. This method may be used to check the polarity and the phase assignment along the secondary wiring. However, this requires one person to operate the battery switch and another person to perform the measurement at exactly the same time at another location.

In other examples, an AC voltage test with phase comparison may be performed. In this test, an AC voltage or an AC current is applied to one side of the transducer and the phase of the voltage or current on the other side is determined, for example using an oscilloscope, a special phase-measuring device or a relay testing device having this function. If the phase comparison shows approx. 0°, the polarity is correct; in the case of approx. 180°, the polarity is inverted. If the expected signal is not able to be measured at a specific test point, this generally indicates a wiring problem. The phase comparison is able to be performed simply directly on the transducer. To test the secondary winding to the relay or counter, the same AC voltage reference must be available at the respective measurement location. To this end, either a separate cable having the AC voltage reference is routed to the measuring point or a common reference, such as the mains AC voltage, is used. In the second case, it must be ensured that the same phase of the mains voltage is available at all measuring points. Many power engineering systems use a three-phase current system.

Likewise, many test devices have at least three current or voltage outputs. These test devices may therefore be used to inject test signals in parallel and to test the wiring of all phases in one operation. By way of example, a test signal having different amplitudes for the different phases may be used for this purpose. It is possible here in particular to use amplitudes for currents and voltages the combination and/or subtraction of which give rise to new amplitudes that otherwise do not occur.

### EXAMPLE

| | | | |
|---|---|---|---|
| L1 = 3 | L1 + L2 = 8 | L1 − L2 = −2 | L1 + L2 + L3 = 17 |
| L2 = 5 | L1 + L3 = 12 | L1 − L3 = −6 | L1 + L2 − L3 = −1 |
| L3 = 9 | L2 + L3 = 14 | L2 − L3 = −4 | L1 − L2 + L3 = 7 |
| | | | −L1 + L2 + L3 = 11 |

This makes it possible to detect wiring errors based on the measured amplitude, for example if the return conductor of one phase is connected incorrectly.

However, the current or voltage amplitudes have to differ to a relatively great extent in order to be able to perform an unambiguous assignment. It is therefore not always possible to work with amplitudes close to the nominal range of the equipment (for example 1 A, 5 A or 100 V). It is also often the case in practice that there are multiple parallel connections or ground connections. In these cases, a current division or voltage division is implemented depending on the respective resistances. Unambiguous phase detection is then no longer possible.

### SUMMARY OF THE INVENTION

There is a need for improved options for testing wiring of an electrical installation having multiple circuits, these options being able to be performed quickly and reliably using simple means.

According to the present invention, provision is made for a method for testing wiring of an electrical installation having multiple circuits and a test device for testing wiring of an electrical installation having multiple circuits, as defined in the independent claims. The dependent claims define embodiments of the invention.

A method according to the invention for testing wiring of an electrical installation having multiple circuits comprises generating multiple test signals. Each of the multiple test signals has a combination of predefined harmonics having at least one, preferably at least two higher harmonics. The amplitude and/or phase position (hereinafter often referred to as “phase” for short) of the at least one higher harmonic of the multiple test signals are different.

In other words, each of the multiple test signals comprises a combination of predefined harmonics. At least one higher harmonic of these predefined harmonics is varied in each case differently in terms of phase and/or amplitude in a respective one of the multiple test signals. Each test signal thus has its own unique combination of amplitude and phase in the at least one harmonic.

By way of example, each of the multiple test signals comprises one or more harmonics that are the same in each of the multiple test signals (in particular including in terms of phase and amplitude). Each of the test signals furthermore comprises at least one further higher harmonic. This at least one further higher harmonic has a certain phase variation and/or amplitude variation for each of the multiple test signals. The phase and/or amplitude of this at least one further higher harmonic are therefore different in the different test signals.

By way of example, in each of the multiple test signals, the first, second and third harmonics may be the same, and the fourth and fifth harmonics, which correspond in this example to the at least one higher harmonic, may have different phases and/or amplitudes in the different test signals. In one simple example, each test signal may comprise a first harmonic and a second harmonic. The first harmonic is the same in all test signals, and the second harmonic has different phases in the different test signals.

The following designations are used for this description. A fundamental of the frequency f is referred to as first harmonic. A double-frequency oscillation (2f) is referred to as second harmonic. Generally speaking, the oscillation with the n-times frequency nf is the nth harmonic. Higher harmonics is the name given to all harmonics other than the first harmonic. The nth harmonic is referred to here as the (n−1)th higher harmonic.

The term “phase” has the following meanings in this description. Firstly, it is used in connection with a multi-phase AC current. By way of example, in electrical engineering, one form of multi-phase AC current is called a three-phase AC current, which consists of three individual AC currents or AC voltages of the same frequency, which are fixedly shifted by 120° from one another in terms of their phase angles. Each of these individual AC currents or each of these individual AC voltages may be assigned components of a multi-phase electrical installation, for example a conductor of a power transmission cable or a winding of a transformer or generator. The multi-phase electrical installation may thereby have multiple circuits coupled to one another, which are referred to as phases.

On the other hand, the term “phase” is also used in this description to describe the phase position of periodic signals in relation to one another within an electrical signal. By way of example, an electrical signal, for example a voltage, may comprise a 50 Hz sinusoidal oscillation and a 100 Hz sinusoidal oscillation. The phase position, or “phase” for short, describes the phase angle between the zero crossings of these oscillations.

Each of the multiple test signals may have a waveform that is asymmetric in the time domain. The waveform that is asymmetric in the time domain comprises a first harmonic (fundamental). The waveform is periodic with the frequency of this fundamental. Asymmetric in the time domain means that the waveform, which is plotted as a signal level over time, cannot be mapped to itself by mirroring on a signal level axis perpendicular to the time axis. One example of such a waveform that is asymmetric in the time domain is the tilting oscillation or sawtooth oscillation with for example a rising edge having a small slope and a falling edge having a large (but negative) slope in terms of magnitude.

By way of example, each of the multiple test signals may have a waveform that is asymmetric in the time domain and that is formed by way of a superimposition of a first harmonic, a second harmonic and a third harmonic each having corresponding amplitude factors. In this case, the waveform that is asymmetric in the time domain comprises, for example, in addition to a fundamental, at least a second and third harmonic. In another example, the waveform that is asymmetric in the time domain may comprise, in addition to the fundamental, only either the second or third harmonic. The at least one higher harmonic may comprise for example two higher harmonics, namely a fourth harmonic and a fifth harmonic, wherein the fourth and fifth harmonics differ, in the different test signals, in terms of amplitude and/or phase. The waveform that is asymmetric in the time domain, formed from the fundamental and the second and third harmonics, may have the fourth and fifth harmonics having the different amplitudes and/or phases superimposed on it. By way of example, a first test signal of the multiple test signals, in addition to the fundamental and the second and third harmonics, may have a fourth harmonic having an amplitude factor of 1.35/16 and a phase offset of +30° relative to an amplitude or phase of the fundamental and a fifth harmonic having an amplitude factor of 1/25 and a phase offset of −30° relative to an amplitude or phase of the fundamental. A second test signal of the multiple test signals, in addition to the fundamental and the second and third harmonics, may have a fourth harmonic having an amplitude factor of 1/16 and a phase offset of −30° relative to an amplitude or phase of the fundamental and a fifth harmonic having an amplitude factor of 0.5/25 and a phase offset of −30° relative to an amplitude or phase of the fundamental. A third test signal of the multiple test signals, in addition to the fundamental and the second and third harmonics, may have a fourth harmonic having an amplitude factor of 1/16 and a phase offset of 0° (that is to say without a phase offset) relative to an amplitude or phase of the fundamental and a fifth harmonic having an amplitude factor of 0.5/25 and a phase offset of −30° relative to an amplitude or phase of the fundamental. It is important in the above example that the test signals differ from one another, at least in one of the fourth and fifth harmonics, at least in terms of amplitude or phase. In principle, it is also sufficient for example if the test signals differ from one another, for example, only in the fourth harmonic in terms of phase. The more clearly the test signals differ from one another, for example through different phases and amplitudes in both the fourth and fifth harmonics, the more reliably the test signals are able to be identified, as is important in the method, as will be explained below.

Overall, for example, the combination of the harmonics of the multiple test signals is designed such that any linear combinations of the multiple test signals essentially also have the same properties in the time domain as the individual test signals. This may be achieved for example in that the test signals differ from one another only in terms of the higher harmonics (for example the fourth and fifth harmonics) and are phase-synchronous with regard to the fundamental. If the higher harmonics (for example phase and/or amplitude of the fourth and fifth harmonics) are changed accordingly, it is also possible to detect which individual signals occur in a sum signal, that is to say the linear combination. The individual signals are thus able to be detected, but it is also easy, for the sum signal, to establish the partial signals of which it consists.

The multiple test signals thus generated are injected via multiple first connections, which are assigned to the multiple circuits of the electrical installation, at a first point of the electrical installation. The multiple circuits may for example comprise multiple phases of the electrical installation. A different test signal of the multiple test signals is injected into each first connection of the multiple first connections. In other words, a different test signal is injected into each circuit of the electrical installation at the first point.

At a second point of the electrical installation, multiple measurement signals may be acquired at multiple second connections, which are assigned to the multiple circuits. By way of example, in the case of a substation, the first point may be at an input of the substation and the second point may be at one of the outputs of the substation. In another example, the first point may be on a first side of a transformer and the second point may be on a second side of the transformer. The injected test signals and the acquired measurement signals may be taken as a basis for determining an assignment between in each case a first connection of the multiple first connections and a second connection of the multiple second connections in order for example to test the wiring of the electrical installation on the basis of the assignments. Since the injected test signals are different, it is possible to establish unambiguously which test signal at which of the second connections has led to a corresponding measurement signal, such that it is possible to determine an unambiguous assignment between the first connections and the second connections. By way of example, it is possible to easily establish mix-ups, but also interruptions, based on the test signals.

By way of example, in the case of a wiring error, it is possible to ascertain an assignment that does not correspond to a desired or predefined assignment, or no assignment, or no complete assignment, is possible, for example due to interruptions or couplings with completely incorrect circuits. In the error-free case, on the other hand, it is possible to ascertain an assignment that corresponds to a predefined “target assignment”.

The test signals are thus identified unambiguously through the different phases and/or amplitudes of the at least one higher harmonic of the different test signals, for example through the different phases and/or amplitudes of the fourth and fifth harmonics in the different test signals. Adding a further harmonic, for example the sixth harmonic, makes it possible to increase the number of different identifications and thus the number of different test signals, in order for example to enable test signals for testing wiring of an electrical installation having more than three phases or circuits, for example for testing two three-phase installation parts, that is to say a total of six phases, or installation parts having multiple circuits, for example having six or more circuits. In principle, however, it is also sufficient if only one higher harmonic has different phases and/or amplitudes in different test signals. If for example three different phases and three different amplitudes are used in the fourth harmonic, nine different test signals may already be generated. In another example, only three different phases are used in the fourth harmonic, thereby already making it possible to generate three different test signals. However, the more distinguishing features are present, the better the different test signals are able to be distinguished from one another.

The multiple test signals may be injected simultaneously into the multiple first connections. The multiple measurement signals may likewise be acquired simultaneously. Due to the identification of the test signals based on the different phases and/or amplitudes of certain harmonics, the multiple measurement signals that are acquired at the second point of the electrical installation are able to be assigned unambiguously to the corresponding test signals, even if the test signals are carried simultaneously by the electrical installation. Appropriate measurement wiring for injecting the test signals and for capturing the measurement signals may therefore be implemented at a point in time, and the wiring may be checked without changing the measurement wiring. The wiring is thereby able to be tested quickly. Wiring errors are able to be avoided because the measurement wiring does not have to be changed in order to check the wiring of all circuits and/or phases.

According to one embodiment, the first harmonic, that is to say the fundamental, has a frequency that is not equal to a mains frequency or nominal frequency of the electrical installation. The first harmonic may for example have a frequency in the range of 50 to 60 Hz, in particular a frequency in the range of 51 to 55 Hz, for example a frequency of 52.6 Hz. Since the first harmonic of the test signals is not equal to the mains frequency of the electrical installation, it is possible to avoid interference from other installation parts that are in operation. Installation parts that are in operation usually generate interference signals at mains frequency, that is to say for example at 50 Hz or 60 Hz, as well as interference signals having higher harmonics thereof. If the fundamental and the higher harmonics of the test signals deviate from this mains frequency and the corresponding higher harmonics, the interference signals from other installation parts that are in operation are easily able to be detected in the measurement signals and filtered out. Since the fundamental has a frequency that does not deviate to a great extent from the nominal frequency of the electrical installation, the test signals are suitable for transmission via the electrical installation, for example via current or voltage converters having transformers and/or capacitances.

In one embodiment, an amplitude of an nth harmonic of the higher harmonics, in which the phase and/or amplitude is not used for identification, has an amplitude factor of 1/n² relative to an amplitude of the fundamental. By way of example, the second and third harmonics described above may have a corresponding amplitude factor. Such amplitude factors make it possible to achieve the waveform that is asymmetric in the time domain. Waveforms comprising the first to third harmonics having an amplitude factor of 1/n² have for example a sawtooth-like waveform having a steep rising edge and a shallow falling edge, such that the waveform is asymmetric in the time domain. Furthermore, the test signals generated in this way have substantially no DC component on average, such that it is possible to avoid saturation of current or voltage converters in the electrical installation. The sawtooth-like waveform is also essentially preserved if the at least one higher harmonic having a changed amplitude and/or phase is additionally superimposed, provided that the amplitude is of the order of magnitude of 1/n², for example 1.5/n² or 0.5/n².

According to one embodiment, the assignments are determined by determining amplitudes and phases of spectral components for frequencies of the harmonics in the measurement signals. The amplitudes and phases of the spectral components are compared with amplitude threshold values and phase threshold values, respectively. The amplitude threshold values may be set on the basis of an amplitude of a fundamental. The amplitude and/or phase positions of the fundamental may be determined from the measurement signal.

In one embodiment, the at least one higher harmonic comprises fourth and fifth harmonics. The fourth harmonic has an amplitude factor of 1.35/16 or 1/16 or 0.65/16, and the fifth harmonic has an amplitude factor of 1.5/25 or 1/25 or 0.5/25 relative to an amplitude of the fundamental. As already discussed above, an amplitude of one of the other nth higher harmonics of the predefined harmonics may have an amplitude factor of 1/n² relative to an amplitude of the fundamental.

By way of example, the fourth harmonic may have a phase offset of +30° or 0° or −30°, and the fifth harmonic may have a phase offset of +30° or 0° or −30° relative to a phase of the fundamental. In other examples, the phase offset of the fourth or fifth harmonic may for example be +20° or 0° or −20° relative to a phase of the fundamental. The phase offset may be selected for example in the range of +/−90°, preferably in the range of +/−45°, more preferably in the range of +/−30° relative to a phase of the fundamental.

According to a further embodiment, the method furthermore comprises determining polarities of the acquired measurement signals in order to test the wiring of the electrical installation depending on the determined polarities. In particular, the asymmetric waveform of the test signals in the time domain may enable simple and reliable determination of the polarity. If for example the wiring of a transformer is incorrect, for example if connections on one side of the transformer have been mixed up, the measurement signal may have a polarity opposite that of the corresponding test signals. In the case of a waveform that is asymmetric in the time domain, the opposite polarity is able to be detected easily. If for example the test signal has a steep rising edge and a shallow falling edge, a measurement signal having opposite polarity has a shallow rising edge and a steep falling edge. A corresponding error in the wiring is thus able to be established.

To determine polarities of the acquired measurement signals, it is possible, for example, for a respective measurement signal of the acquired measurement signals, to determine a derivative of the measurement signal and to generate a comparison signal by comparing the derivative with a threshold value. By way of example, the comparison signal may have a positive value for ranges of the derivative having a positive slope above the threshold value and negative value, of equal absolute value, for ranges of the derivative having a negative slope above the threshold value. If the average of the comparison signal is then determined, for example as a sliding average or over a period of the fundamental of the test signal, the polarity of the measurement signal is able to be determined on the basis of the average of the comparison signal.

As an alternative or in addition, determining polarities of the acquired measurement signals for a respective measurement signal may comprise determining a correlation coefficient, in particular a correlation factor, on the basis of the respective measurement signal and the waveform that is asymmetric in the time domain. The polarity of the respective measurement signal may be determined on the basis of the correlation factor. In the case of identical polarity, the correlation factor is positive and has for example a value close to 1. In the case of opposite polarity, the correlation factor is negative and has for example a value close to −1.

A test device according to the invention for testing wiring of an electrical installation having multiple circuits comprises a test signal generation device and an injection device. The test signal generation device is configured to generate multiple test signals. Each of the multiple test signals has a combination of harmonics having at least one higher harmonic. The amplitude and/or phase of the at least one higher harmonic are different in the multiple test signals. The injection device is configured to inject the multiple test signals into multiple first connections at a first point of the electrical installation. The multiple first connections are assigned to the multiple circuits of the electrical installation. A different test signal of the multiple test signals is injected into each first connection of the multiple first connections. Since the test signals are based on different combinations of harmonics, the test signals injected into the multiple first connections at the first point are different.

The test device may, in some exemplary embodiments, furthermore comprise an acquisition device and a processing device. The acquisition device is configured to acquire multiple measurement signals at multiple second connections, which are assigned to the multiple circuits, at a second point of the electrical installation. The first point and the second point are different points of the electrical installation. The multiple circuits may for example comprise multiple phases of the electrical installation. By way of example, the first point may be on one side of a transformer of the electrical installation and the second point may be on the other side of the transformer. The acquisition device is configured to determine assignments between in each case a first connection of the multiple first connections and a second connection of the multiple second connections on the basis of the injected test signals and the acquired measurement signals.

The test signal generation device may comprise multiple single-phase devices that each generate only one test signal. The multiple single-phase devices may be configured such that they each generate one of the multiple test signals based on different amplitudes and/or phases of the at least one higher harmonic. As an alternative or in addition, the test signal generation device may comprise multiple multi-phase devices, for example two three-phase devices, in order to generate six test signals using which six circuits or phases are able to be tested simultaneously. The devices may in this case be connected in order to achieve the same phase position for the fundamentals, which simplifies the detection of superimposed signals. However, the detection of the individual phases also works when the devices are not coupled.

The test device may be designed in particular to perform the method described above or one of its embodiments and therefore also comprises the advantages described above in connection with the method.

### BRIEF DESCRIPTION OF THE FIGURES

The invention is explained in more detail below on the basis of the drawings with reference to embodiments. In the drawings, identical reference signs refer to identical elements.

FIG. 1 schematically shows a test device for testing wiring of an electrical installation having multiple phases according to one embodiment.

FIG. 2 shows a method for testing wiring of an electrical installation having multiple phases according to one embodiment.

FIG. 3 schematically shows multiple test signals according to one embodiment, which have a waveform that is asymmetric in the time domain and a combination of higher harmonics.

FIG. 4 schematically shows time derivatives of the multiple test signals from FIG. 3.

FIG. 5 schematically shows a comparison signal formed by comparing a derivative of a test signal with a threshold value.

FIG. 6 schematically shows a further test device for testing wiring of an electrical installation having multiple circuits according to one embodiment.

### DETAILED DESCRIPTION OF EXEMPLARY EMBODIMENTS

The present invention is explained in more detail below on the basis of embodiments with reference to the figures. In the figures, the same reference signs denote the same or similar elements. The figures are schematic representations of various embodiments of the invention. Elements illustrated in the figures are not necessarily illustrated true to scale. Rather, the various elements illustrated in the figures are rendered in such a way that the function and purpose thereof are able to be understood by those skilled in the art.

Connections and couplings illustrated in the figures between functional units and elements may be implemented as direct or indirect connections or couplings. A connection or coupling may be implemented in wired or wireless form.

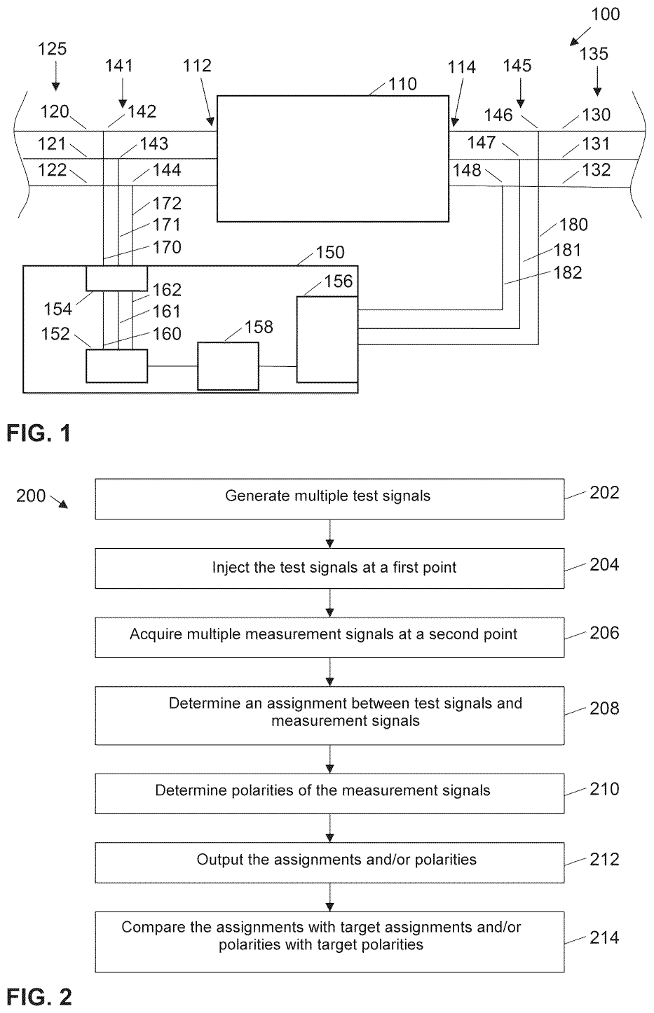

FIG. 1 schematically shows a section of an electrical installation 100 to which a test device 150 for testing wiring of the electrical installation 100 is connected. The electrical installation 100 is a multi-phase electrical installation. Many power engineering systems use a three-phase current system. In the example shown in FIG. 1, the electrical installation 100 is a three-phase system. By way of example, the electrical installation 100 may comprise a high-voltage installation or part thereof. The electrical installation 100 comprises an electrical component 110, on which two three-phase connections are provided. The electrical component 110 may include for example a three-phase circuit breaker, a three-phase transformer, multiple transformers, capacitances, current and voltage converters or intermediate converters. On a first side 112, the electrical component 110 has connections that are connected to outer conductors 120 to 122 of a three-phase power line 125. On a second side 114, the electrical component 110 has connections that are connected to outer conductors 130 to 132 of a second three-phase power line 135. The electrical component 110 may have further connections, for example for grounding or for a neutral conductor of a star-connected three-phase system, with these further connections however not being shown for reasons of clarity. Wiring errors may occur when installing the electrical component 110. By way of example, two outer conductors, for example the outer conductors 120 and 121, may be connected the wrong way round on the first side 112 of the electrical component 110. Following installation or repair of the electrical installation 100, it may therefore be necessary to check the wiring.

In order to check the wiring, the test device 150 shown in FIG. 1 may be electrically coupled to both sides 112, 114 of the electrical component 110.

The test device 150 comprises a test signal generation device 152, which generates multiple test signals. To test the three-phase electrical installation 100, the test signal generation device 152 generates for example three test signals 160 to 162. The test device 150 furthermore comprises an injection device 154 by way of which the test signals 160 to 162 are injected into multiple first connections 142 to 144 at a first point 141 of the electrical installation 100 via corresponding lines 170 to 172. The injection device 154 may for example adapt the test signals from the test signal generation device 152 to a nominal range of the electrical component 110 and provide them at three connections. A set of lines comprising the three lines 170 to 172 may be connected to the three connections of the injection device 154. At the first point 141, for example a comparatively easily accessible distribution upstream of the electrical component 110, the line 170 may be connected to the outer conductor 120, such that a first test signal is injected into the outer conductor 120. The line 171 may be connected to the outer conductor 121 in order to inject a second test signal into the outer conductor 121. The line 172 may be connected to the outer conductor 122 in order to inject a third test signal into the outer conductor 122. A corresponding test signal is thus injected into each phase on the first side 112 of the component 110.

The test device 150 may furthermore comprise an acquisition device 156, which is connected, via corresponding lines 180 to 182, to the three outer conductors 130 to 132, which are connected to the second side 114 of the component 110, at a second point 145 of the electrical installation 100 via corresponding second connections 146 to 148. The second point 145 may be located on an easily accessible distribution of the electrical installation 100. A corresponding measurement signal is thus able to be acquired for each phase on the second side 114.

The test device 150 may furthermore comprise a processing device 158. The processing device 158 comprises for example an electronic controller, for example a microprocessor controller, which is able for example to execute a computer program. The processing device 158 may be coupled to the test signal generation device 152 and the acquisition device 156 in order to drive them in a coordinated manner, as will be described in detail below. In other examples, the processing device 158 is not connected to the test signal generation device 152 and the test signal generation device 152 generates the test signals independently of any control by the processing device 158. It is therefore clear that the test signal generation device 152, the injection device 154, the acquisition device 156 and the processing device 158 do not necessarily have to be formed in one and the same housing or in one unit, but rather may comprise spatially independent units having their own housings. By way of example, the test signal generation device 152, together with the injection device 154, may form a unit that is able to be operated and set up independently of any other unit comprising the acquisition device 156 and the processing device 158. The test device 150 is thereby able to be used even in large electrical installations in which the first point 141 is a large distance away from the second point 145, without the need for correspondingly long lines 170 to 172 or 180 to 182.

The way in which the test device 150 works will be described in detail below with reference to FIGS. 2 to 5. FIG. 2 shows a method 200 having method steps 202 to 214 that are able to be carried out by the test device 150 in order to test the wiring of the electrical installation 100. In particular, steps 206 to 214 may in this case be optional or replaced by other steps based on the test signals generated and injected in steps 202 and 204. At least some of the processing steps shown in FIG. 2 may be performed in particular using the processing device 158, for example by way of a computer program that is executed by the processing device 158.

In step 202, multiple test signals are generated. In detail, a separate test signal Pₚ(t) is generated for each phase, having a waveform that is asymmetric in the time domain and a combination of predefined harmonics having at least one higher harmonic. The index p denotes the phase for which the test signal Pₚ(t) is intended. The multiple test signals differ from one another in that the amplitude and/or phase position (hereinafter also phase for short) are different in the at least one higher harmonic. By way of example, the test signals may be based on a common signal P(t), which has a waveform that is asymmetric in the time domain. The waveform of the common signal P(t) may be approximated to a sawtooth waveform. For this purpose, it is possible for example to use sine signals having different amplitude and frequency, these approximating the sawtooth waveform by way of Fourier synthesis. By way of example, a signal according to the following equation may be used as common signal P(t):

$$P ( t ) = A {\sum }_{n = 1}^{k} \frac{1}{{n}^{2}} sin ( 2 π {nf}_{g} t )$$

A here represents the amplitude of the entire signal, k represents the number of harmonics used and f_{g} represents the fundamental frequency of the signal. The term

$$\frac{1}{{n}^{2}}$$

weights the individual sine functions in order overall to approximate the sawtooth waveform.

By way of example, it is possible to form a signal with A=1, k=3, and f_{g}=52.6 Hz. In other examples, A may also be selected such that a root mean square (RMS) of the signal is approximately 1. By way of example, it is possible to select A˜0.962.

Each of the test signals Pₚ(t) furthermore comprises at least one higher harmonic, wherein the amplitude and/or phase of this at least one higher harmonic are/is different in the different test signals. In the example described below, the at least one higher harmonic comprises two higher harmonics, namely the fourth and fifth harmonics. In other examples, further or different harmonics may be used to distinguish between the different test signals. In principle, however, one higher harmonic is already sufficient to distinguish between the different test signals. The advantage of using multiple higher harmonics is that this improves the distinction between the test signals, for example when the test signals are subject to interference or noisy. The test signals are coded by the different amplitudes and/or phases in the at least one higher harmonic. This coding may for example represent phase information in a multi-phase electrical system that indicates the phase of the electrical installation 100 to which the test signal is assigned.

In order to code the phase information into the sawtooth-like signal, the amplitude and phase of for example two higher harmonics are changed slightly. By way of example, the fourth and fifth harmonics are changed so as to code this phase information, while the fundamental and the second and third harmonics remain unchanged. In total, only five harmonics are used in order to limit the bandwidth of the test signal. The following equation shows the definition of the modified test signal y(t) containing five harmonics (k=5).

$$y ( t ) = {\sum }_{n = 1}^{k} {a}_{n} \frac{1}{{n}^{2}} sin ( 2 π {nf}_{g} t + {φ}_{n} )$$

The amplitude variations an and phase variations φₙ that are used may be represented by introducing an amplitude modifier A[n] and a phase modifier P[n] for the nth harmonic. By way of example, both may have three specific values, which are for example denoted −1, 0 and +1. The assignments to an and on that are used in the above equation are shown in Table 1 below.

TABLE 1
Amplitude and phase variation

| Param- | Coefficients | | | | |
|---|---|---|---|---|---|
| eter | n = 1 | n = 2 | n = 3 | n = 4 | n = 5 |
| aₙ | 1 | 1 | 1 | A[4] = 1: 1.35 | A[5] = 1: 1.50 |
| | | | | A[4] = 0: 1.00 | A[5] = 0: 1.00 |
| | | | | A[4] = −1: 0.65 | A[5] = −1: 0.50 |
| φₙ | 0 | 0 | 0 | P[4] = 1: 0.5 rad | P[5] = 1: 0.5 rad |
| | | | | P[4] = 0: 0.0 rad | P[5] = 0: 0.0 rad |
| | | | | P[4] = −1: −0.5 rad | P[5] = −1: −0.5 rad |

It is clear that the amplitude and phase variations may also be represented in other ways, for example directly by the corresponding amplitude factors and phase angles. It is also clear that a number other than three values may be used for the variation, for example two or more than three. The phase angles are indicated in radians in Table 1. 0.5 rad corresponds to approximately 28.6°. In other examples, other phase angles may be used for the variation, for example +/−20° or +/−40°.

Due to the comparatively small amplitudes of the fourth and/or fifth harmonics, the asymmetric waveform changes only to an insignificant extent. Lower harmonics, such as for example the second and third harmonics, are less suitable for coding the phase information, since they affect the asymmetry of the signal in the time domain significantly and could therefore complicate detection, in particular of polarity. Harmonics that are even higher, in particular seventh or higher harmonics, are also less suitable, since current and voltage converters usually attenuate high frequencies to a much greater extent, and could thus impair transmission and detection.

This amplitude and phase variation scheme having three fixed values for the two amplitude modifiers and the two phase modifiers makes it possible to code 3²⁺²=81 different codewords. It is clear that, as an alternative, only one amplitude variation or only one phase variation may be used. By way of example, in the case of only one phase variation, the amplitude modifiers A[n] have the value 0, that is to say the amplitude variation an has the value 1.

In order to increase the robustness of the coding, for example, only five of the 81 possible codewords are used, which are referred to below as CWS, CW1, CW2, CW3 and CW4. CWS represents an unchanged sawtooth-like test signal. CW1 CW4 may be used to identify four different phases or circuits of an electrical installation. The codeword CW4 for the fourth phase is generally not required in three-phase installations and grids, but is discussed here at least for reasons of symmetry.

Table 2 below shows one example of an assignment of the codewords to the amplitude and phase modifiers A and P.

TABLE 2
Mapping of codewords to amplitude and phase modifiers

Amplitude and phase modifiers

| | | A[4] | P[4] | A[5] | P[5] |
|---|---|---|---|---|---|
| Codeword | CWS | 0 | 0 | 0 | 0 |
| | CW1 | +1 | −1 | −1 | +1 |
| | CW2 | −1 | −1 | +1 | +1 |
| | CW3 | +1 | +1 | −1 | −1 |
| | CW4 | −1 | +1 | +1 | −1 |

All different codewords differ from one another in terms of at least two modifiers. The sum of the differences between the amplitude and phase modifiers A and P for each combination of codewords used may be calculated in order to obtain the Hamming distance between the codewords. Table 3 below shows the resulting Hamming distances.

TABLE 3
Hamming distances between codewords

| | | from codeword | | | | |
|---|---|---|---|---|---|---|
| Hamming distance | | CWS | CW1 | CW2 | CW3 | CW4 |
| to codeword | CWS | — | 4 | 4 | 4 | 4 |
| | CW1 | 4 | — | 4 | 4 | 4 |
| | CW2 | 4 | 4 | — | 4 | 4 |
| | CW3 | 4 | 4 | 4 | — | 4 |
| | CW4 | 4 | 4 | 4 | 4 | — |

There is a minimum distance of 4 between all of the codewords used, which makes it possible to detect and correct a single error, such as an incorrectly detected amplitude or phase value. In addition, two incorrectly detected modifiers may be detected as errors, but cannot be corrected. In the case of a single incorrect symbol, the next valid codeword with a Hamming distance of 1 is used. If the distance is greater, it is considered to be an incorrect codeword.

In this context, this would mean that the phase information of a highly distorted signal cannot be decoded correctly, but it is still able to be detected that it is a valid polarity test signal.

A signal having a fundamental frequency of 52.6 Hz may be used for the method. Limiting the signal to the fifth harmonic gives 263 Hz as the highest frequency. Because the encoding that is used is static, there are no higher frequencies due to modulation. Conventional current and voltage converters are able to transmit these relatively low frequencies without a great amount of attenuation or phase shifts.

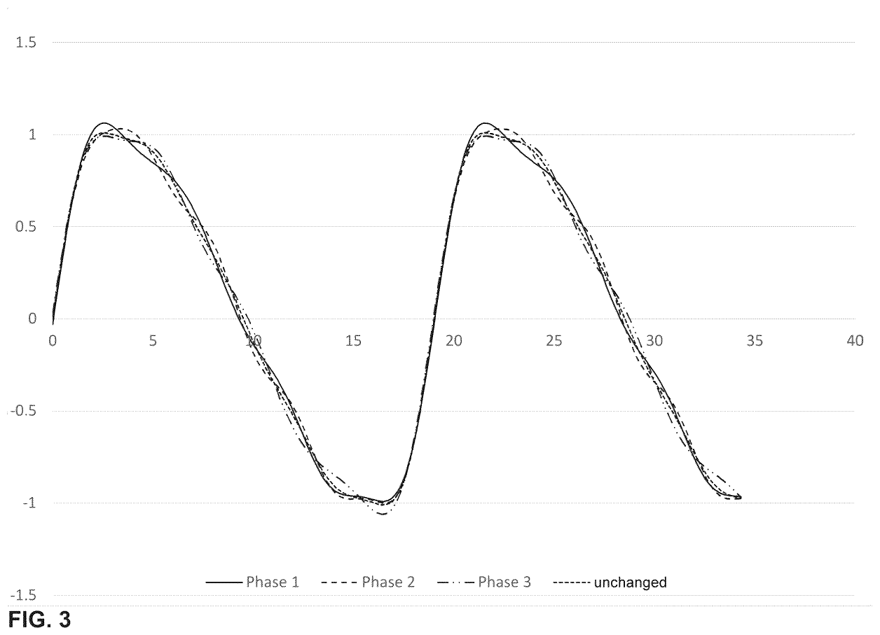

FIG. 3 shows waveforms of the test signals for the phases 1, 2 and 3 based on the codings CW1, CW2 and CW3 and the unchanged test signal based on the coding CWS. As may be seen from FIG. 3, the asymmetric waveform in the time domain is clearly recognizable for all test signals, that is to say the signals all essentially have a comparatively steep rising edge and a falling edge that is comparatively shallow compared to the rising edge.

In step 204, the generated test signals 160 to 162 for the phases 1, 2 and 3 are injected into the outer conductors 120 to 122 at the first point 141 via the first connections 142 to 144. The test signals 160 to 162 may be injected simultaneously. The test signals injected in this way pass through the electrical component 110, which comprises for example one or more transformers or capacitances or other power engineering equipment, such as circuit breakers for example. On the second side 114, the electrical component 110 outputs output signals on the three outer conductors 130 to 132 due to the injected test signals. When an electrical component 110 is connected correctly, it is expected for example that the test signal injected on the outer conductor 120 will essentially be output on the outer conductor 130, for example with a changed voltage in the case of a transformer. However, it would be expected that the waveform would be essentially unchanged. Similarly, when the electrical component 110 is connected correctly, it is expected for example that the signal injected into the outer conductor 121 will essentially be output onto the outer conductor 131 and that the signal injected into the outer conductor 122 will essentially be output on the outer conductor 132.

In the case of incorrect wiring, in which the outer conductors 121 and 122 have been connected the wrong way round, the signal injected onto the outer conductor 121 is output, conversely, onto the outer conductor 132, and the signal injected onto the outer conductor 122 is output onto the outer conductor 131.

In step 206, multiple measurement signals are acquired at the second point 145. The multiple measurement signals may be acquired simultaneously or sequentially. In the acquisition device 156, the acquired measurement signals may optionally be pretreated, for example by filtering. By way of example, the measurement signals may be preprocessed using analogue and/or digital filters in order for example to suppress interference caused by resistive, inductive or capacitive coupling, for example, a resistive voltage drop due to a current flow through a common return conductor. Such interference may affect the outer conductors 120 to 122 and 130 to 132, for example from neighboring systems that are in operation. Furthermore, for example, notch filters for mains frequencies, for example at 50 Hz, 60 Hz or 16.7 Hz or a combination thereof, may be used to filter out interference from neighboring systems. Further notch filters may be used to filter the measurement signals for higher harmonics of the mains frequency. As an alternative or in addition, low-pass filters may be applied to the measurement signals to remove higher harmonics and other interference. A cutoff frequency may in this case be higher than the frequency of the highest harmonics used in the test signals. Finally, a high-pass filter may be applied to the measurement signals to remove low-frequency interference, wherein the cutoff frequency may be lower than the fundamental frequency of the test signals. The preprocessing of the measurement signals makes it possible to increase the reliability of the wiring check and susceptibility to interference from neighboring systems that are in operation.

In step 208, an assignment between test signals and measurement signals is determined. In other words, in step 208, the test signals are identified in the measurement signals. Identifying the individual test signals in the measurement signals may comprise determining amplitudes and phases of spectral components for frequencies of the predefined harmonics, in particular the higher harmonics used for the coding, in the measurement signals. The amplitudes and phases of these spectral components may be compared with amplitude threshold values and phase threshold values, respectively. The amplitude threshold values may be set depending on an amplitude of a fundamental of the waveform that is asymmetric in the time domain.

If the fundamental frequency f_{g} has been selected appropriately as described above, for example at 52.6 Hz, there are no overlaps with the mains frequency or higher harmonics of the mains frequency.

As described above, the information used to identify a phase is coded robustly in sawtooth-like test signals. This makes it possible to check correct polarity and phase assignment without the need for a common reference and without a dependency on the signal amplitude.

Modified sawtooth-like test signals may be decoded from the acquired measurement signals in the following steps, for example.

In a first step, the received measurement signal may be filtered using a low-pass filter in order to limit its bandwidth to for example 263 Hz, that is to say to the frequency that was used as the highest frequency when generating the test signals. In the abovementioned example, a fundamental frequency of 52.6 Hz was used, and so the highest frequency of the fifth harmonic is 263 Hz. By way of example, an eighth-order Butterworth low-pass filter may be used as a prefilter.

In a second step, the measurement signal is examined for the frequency components of the five harmonics used in this example. The period durations of each of these signals of interest are known (for example 52.6 Hz and integer multiples thereof) and it is therefore possible for example to use a Goertzel algorithm to carry out a discrete Fourier transform (DFT). The Goertzel algorithm delivers the amplitude and phase and is applied to all frequencies of interest, for example the five frequencies of the five harmonics used. Longer integration intervals of for example 20 periods may be used in order to additionally suppress noise and interference by utilizing an averaging effect.

Finally, the phase information is decoded. The amplitude of the fourth and fifth harmonics is normalized based on the average amplitude of the first three harmonics. By way of example, a discriminator then tests the harmonics for amplitude and phase deviations from the values indicated in Table 1 and gives the detected amplitude and phase modifiers a value of +1 (if >150% of the nominal value), −1 (if <50% of the nominal value), or 0 (if in between) and assigns them to one of the 81 possible codewords. The Hamming distance between the received codeword and all five valid codewords may then be calculated. If a codeword with a distance of 0 or 1 is found, the detector accepts it as a correct codeword. Based on the phase information ascertained in this way, it is possible to ascertain which test signal is contained in which measurement signal, and thus the outer conductor on which an input test signal is output.

If a Hamming distance of two or more is reported, it may be used as a polarity check signal, but no phase information is able to be derived reliably therefrom. However, it is at least detected that the test signal is subject to significant interference, which may be output to an operator.

Based on the assignment between test signals and measurement signals determined in step 208, it is easily possible to establish whether the expected test signals have been acquired at the corresponding outer conductors 130 to 132. In the case of assignments that are not as expected, incorrect wiring may be established.

In step 210, polarities of the measurement signals that were acquired at the second point 145 are determined. The polarity is detected based on the waveform that is asymmetric in the time domain.

By way of example, the polarity may be detected as follows. The amplitudes of the harmonics are compared with the detected fundamental. If the second and third harmonics are within +/−50% of the expected relative amplitude and the phase is +/−˜30° (0.5 rad) within the expected values, this is considered to be a valid sawtooth-like signal, that is to say a sawtooth-like signal with correct polarity. In the case of correct polarity, all harmonics have essentially the same phase as the fundamental wave, aside from the set phase variation. In the case of an inverted signal, each second harmonic in the frequency domain is inverted, resulting in a phase shift of 180°. This is significantly greater than the phase variation. Therefore, a phase value of 0° and 180° (+/−) 30° for the second harmonic, but only 0° (+/−) 30° for the third harmonic, is considered to be a sawtooth-like signal with correct polarity. In the case of a polarity of ˜0°, the polarity is considered to be correct, and in the case of a polarity of ˜180°, it is considered to be incorrect (inverted).

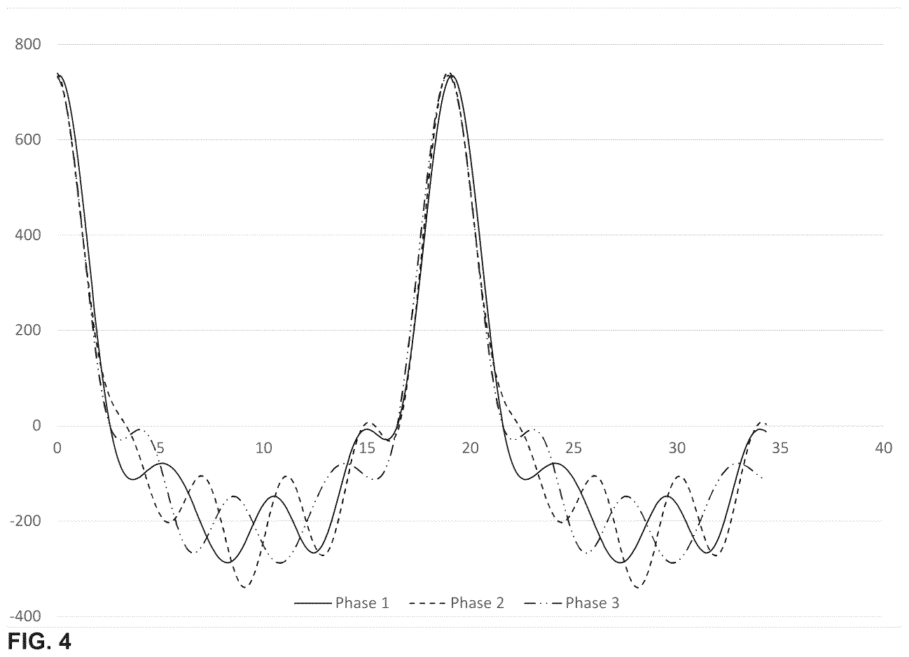

In a further example, polarity may be assessed as follows. For the measurement signals, which may be pretreated as described above, respective derivatives are formed in the time domain. A respective derivative may be ascertained for example through a time-discrete numerical differentiation using differences between signal levels acquired in temporal succession or implicitly through appropriately adapted filter structures, for example by using an analogue operational amplifier as a differentiation circuit or in digital filter structures. FIG. 4 shows resulting derivatives dMₚ(t)/dt for the measurement signals Mₚ(t) for the phases p=1, 2 and 3, which are obtained in response to the test signals for the phases 1, 2 and 3 based on the codings CW1, CW2 and CW3 (in the case of correct wiring and polarity). A corresponding auxiliary signal Qₚ(t) may be formed for each of the derivatives, for example according to the following rule:

$${Q}_{p} ( t ) = \{ \begin{matrix}1 , if \frac{{M}_{p} ( t )}{dt} > δ \\ - 1 , if \frac{{M}_{p} ( t )}{dt} < - δ \\ 0 , otherwise\end{matrix}$$

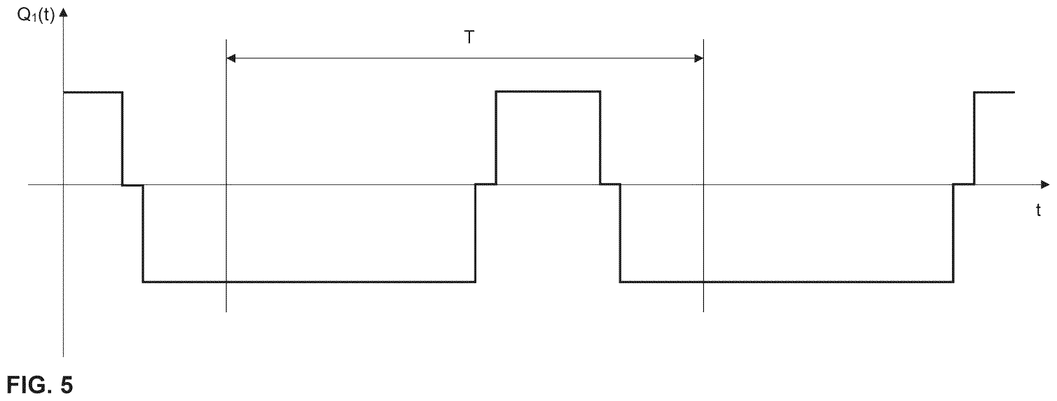

In this case, δ is a threshold value used to suppress noise and other undesired interference. FIG. 5 shows, by way of example, the auxiliary signal Q₁(t) for the test signal for phase 1. Based on the auxiliary signal Qₚ(t), a corresponding average Q̅ₚ̅(̅t̅)̅ is calculated over a certain time. This average may be calculated for example over a discrete time, for example a period duration T of the fundamental of the test signals or continuously by way of a low-pass filter. If this average exceeds a defined positive threshold, then a positive polarity is indicated (short rising edge and long falling edge). If the average falls below a defined negative threshold, a negative polarity is indicated (long rising edge and short falling edge). A polarity change, which may occur for example due to incorrect wiring, is thus able to be determined easily for each phase.

In step 212, the phase assignments and polarities determined in this way may be output, for example, on a display device for a user.

By way of example, a first test signal for phase 1 may be output on line 170, a second test signal for phase 2 may be output on line 171, and a third test signal for phase 3 may be output on line 172. If the electrical installation 100 is wired correctly, the test device 150 indicates, for the line 180, that the first test signal has been detected, for the line 181, that the second test signal has been detected, and for the line 182, that the third test signal has been detected. The test device 150 may furthermore indicate that the test signals were each output and detected with a positive polarity. Wiring errors, for example mixed-up outer conductors or incorrect wiring leading to a polarity reversal, for example at a transformer, are able to be identified by an operator based on the outputs.

As an alternative or in addition, in step 214, the detected phase assignments may be compared with target assignments and/or the detected polarities may be compared with target polarities and a warning may be output automatically if a deviation between the detected state and the target state has been established.

The electrical installation 100 may also have further connections, for example further three-phase connections, the wiring of which may be checked in the same way as described above. These connections may for example concern auxiliary circuits or control circuits, which may also be tested using the above method, depending on the type of circuit.

If multiple circuits or phases are tested, they may use a common neutral conductor (N for L1, L2 and L3) or be completely separate circuits (L1+N1, L2+N2, L3+N3). In this case too, various wiring errors are conceivable and are able to be detected using the method. Multiple ground connections may occur in the event of wiring errors. By way of example, a current clamp may be used to measure the current via the ground connection as one of the multiple measurement signals. The described method makes it possible, using the assignments, to detect which test signals were able to be detected in the ground connection, and thus makes it possible to identify desired and undesired ground connections.

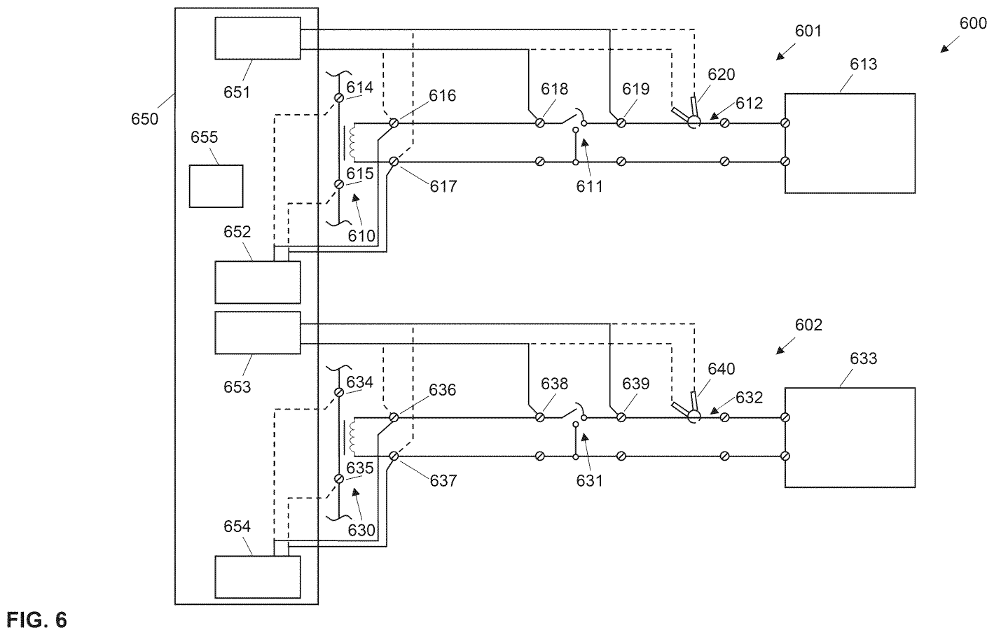

FIG. 6 schematically shows a section of a further electrical installation 600 to which a test device 650 for testing wiring of the electrical installation 600 is connected. The electrical installation 600 comprises multiple circuits that may be assigned to one or more phases. In the example shown in FIG. 6, the electrical installation 600 comprises two circuits 601 and 602 that are essentially separate from one another. However, the circuits 601 and 602 may also be assigned to one phase of a multi-phase system, that is to say the same phase of the multi-phase system, or to multiple different phases of a multi-phase system, or may be connected to one another via their neutral conductors. In other examples, the electrical installation 600 may comprise more than two circuits. By way of example, the electrical installation 600 may comprise a high-voltage installation or part thereof. Each of the circuits 601 and 602 may comprise one or more electrical components, for example current or voltage converters 610, 630, secondary wiring 612, 632, matching converters, test plugs 614-619, 634-639, test switches 611, 631, counters and/or protective devices, such as for example relays 613, 633.

Following installation or repair of the electrical installation 600, it may be necessary to check the wiring. In order to check the wiring, the test device 650 shown in FIG. 6 may be electrically coupled to both circuits 601 and 602.

The test device 650 comprises multiple test signal generation devices that generate multiple test signals. FIG. 6 shows two test signal generation devices 652 and 654 for generating two test signals. The multiple test signals may also be generated by a common test signal generation device. Each of the test signal generation devices 652 and 654 is assigned a corresponding injection device (not shown) by way of which the test signals are injected into the electrical installation 600 at corresponding injection points via corresponding lines. The injection devices may for example adapt the test signals from the test signal generation devices 652, 654 to a nominal range required at the corresponding injection point. In the example shown in FIG. 6, the test signal from the test signal generation device 652 may be injected for example at test plugs 616, 617 on a secondary side of a converter 610, for example a current converter or voltage converter. As an alternative, the test signal from the test signal generation device 652 may also be injected at test plugs 614, 615 on a primary side of the converter 610, as shown by the dashed lines. Injection on the primary side makes it possible to additionally check the polarity and wiring of the converter 610. In the case of injection on the primary side, correspondingly higher currents may be required for current converters and correspondingly higher voltages may be required for voltage converters. Likewise, the test signal from the test signal generation device 654 may be injected for example at test plugs 636, 637 on a secondary side of a converter 630. As an alternative, the test signal from the test signal generation device 654 may also be injected at test plugs 634, 635 on a primary side of the converter 630, as shown by the dashed lines, in order to additionally check the polarity and wiring of the converter 630.

The test device 650 furthermore comprises multiple acquisition devices for acquiring measurement signals. In the example of FIG. 6, the test device 650 comprises two acquisition devices 651 and 653, which are coupled to the first and second circuit 601, 602, respectively, via corresponding lines. By way of example, the acquisition device 651 may be coupled to test plugs 618, 619 at the test switch 611 in order to acquire a voltage at the test switch 611 as a measurement signal. As illustrated by the dashed lines, the acquisition device 651 may, as an alternative, be coupled to test plugs 616, 617 in order to acquire a voltage on the secondary side of the converter 610 or to a current clamp 620 in order to acquire a current through the wiring 612. In the same way, the acquisition device 653 may be coupled to the second circuit 602. As shown in FIG. 6, the acquisition device 653 may be coupled to the test plugs 638, 639 at the test switch 631 in order to acquire a voltage at the test switch 631 as a measurement signal. As an alternative, the acquisition device 653 may be coupled to test plugs 636, 637 in order to acquire a voltage on the secondary side of the converter 630 or to a current clamp 640 in order to acquire a current through the wiring 632.

The test device 650 furthermore comprises a processing device 655, which is shown as a separate component in FIG. 6. In other examples, the processing device 655 may also be designed so as to be integrated with one of the test signal generation devices 652, 654 or the detection devices 651, 653. The processing device 655 comprises for example an electronic controller, for example a microprocessor controller, which is able for example to execute a computer program. The processing device 655 may be coupled to the test signal generation devices 652, 654 and the acquisition devices 651, 653 in order to drive them in a coordinated manner, as will be described in detail below. In other examples, the processing device is not connected to the test signal generation devices 652, 654, and the test signal generation devices 652, 654 generate the test signals independently of any control by the processing device 655. The test signal generation devices 652, 654, the acquisition devices 651, 653 and the processing device 655 do not have to be formed in one and the same housing or in one unit, but rather may comprise spatially independent units having their own housings. By way of example, the test signal generation devices 652, 654 may each form a unit that is able to be operated and set up independently. A further unit may comprise the acquisition devices 651, 653 and the processing device 655 and be coupled to the test signal generation devices 652, 654. The test device 650 is thereby able to be used even in large electrical installations in which the injection points are a large distance away from the measuring points, without the need for correspondingly long lines between the test signal generation devices 652, 654 and the corresponding injection points.

The way in which the test device 650 works corresponds essentially to the way in which the test device 150 works, as described in detail above with reference to FIGS. 1 to 5. As described above, the method 200 shown in FIG. 2 may be carried out by the test device 650 in order to test the wiring of the electrical installation 600.

In step 202, two test signals are generated in this case. A separate test signal Pₚ(t) is generated for each circuit 601, 602, having a waveform that is asymmetric in the time domain and a combination of predefined harmonics having at least one higher harmonic. The index p denotes the circuit for which the test signal Pₚ(t) is intended, for example p=1 for the circuit 601 and p=2 for the circuit 602. The two test signals differ from one another in that the phase positions (hereinafter also phase for short) are different in the at least one higher harmonic. By way of example, the test signals may be based on a common signal P(t), which has a waveform that is asymmetric in the time domain. The waveform of the common signal P(t) may be approximated to a sawtooth waveform. For this purpose, it is possible for example to use sine signals having different amplitude and frequency, these approximating the sawtooth waveform by way of Fourier synthesis. By way of example, a signal according to the following equation may be used as common signal P(t):

$$P ( t ) = A {\sum }_{n = 1}^{k} \frac{1}{{n}^{2}} sin ( 2 π {nf}_{g} t )$$

A here represents the amplitude of the entire signal, k represents the number of harmonics used and f_{g} represents the fundamental frequency of the signal. The term 1/n² weights the individual sine functions in order overall to approximate the sawtooth waveform.

By way of example, it is possible to form a signal with A=1, k=3, and f_{g}=52.6 Hz. In other examples, A may also be selected such that a root mean square (RMS) of the signal is approximately 1.

Each of the two test signals Pₚ(t) furthermore comprises at least one higher harmonic, wherein the phases of this at least one higher harmonic are different in the different test signals. In the example described below, the at least one higher harmonic comprises only one higher harmonic, namely the fourth harmonic. The test signals are thus coded. This coding may for example represent circuit information in the electrical system 600 having the two circuits 601 and 602, indicating the circuit to which the test signal is assigned.

In order to code the circuit information into the sawtooth-like signal, the phase of the fourth harmonic is changed slightly, while the fundamental and the second and third harmonics remain unchanged. In total, only four harmonics are used in order to limit the bandwidth of the test signal. The following equation shows the definition of the modified test signal y(t) containing four harmonics (k=4).

$$y ( t ) = {\sum }_{n = 1}^{k} \frac{1}{{n}^{2}} sin ( 2 π {nf}_{g} t + {φ}_{n} )$$

The phase variations that are used may be represented by introducing a phase modifier P[4] for the fourth harmonic. By way of example, this may have two specific values, which are for example denoted −1 and +1. The assignment to φₙ used in the above equation is for example:

$${φ}_{1} = 0 , \\ {φ}_{2} = 0 , \\ {φ}_{3} = 0 , \\ {φ}_{4} = 0.5 rad for P [ 4 ] = 1 and {φ}_{4} = - 0.5 rad for P [ 4 ] = - 1.$$

Similarly to the description given in connection with the example of FIG. 1, each value of the phase modifier P[4] thus here represents a codeword, for example P[4]=1 is codeword CW1 and P[4]=−1 is codeword CW2.

In step 204, the generated test signals are injected into the circuits 601, 602, as described above. The test signals may be injected simultaneously. The test signals injected in this way pass through the electrical components, which comprise for example one or more transformers or capacitances or other power engineering equipment, such as circuit breakers or test switches for example. Output signals are generated at the measuring points described above on the basis of the injected test signals. When electrical components are connected correctly, it is expected for example that the test signal injected into the circuit 601 will essentially be output at the test plugs 618, 619 of the test switch 611, for example with a changed voltage in the case of injection at the test plugs 614, 615. However, it would be expected that the waveform would be essentially unchanged. Likewise, when electrical components are connected correctly, it is expected for example that the signal injected into the circuit 602 will essentially be output at the test plugs 638, 639 of the test switch 631.

In the case of incorrect wiring, in which for example lines of the first circuit 601 and lines of the second circuit 602 have been connected the wrong way round, the signal injected into the first circuit 601 could, conversely, be present in the second circuit 602 and/or the signal injected into the second circuit 602 could be present in the first circuit 601.

In step 206, multiple measurement signals are acquired, for example as described above, at the test switches 611 and 631. The multiple measurement signals may be acquired simultaneously or sequentially. In the acquisition devices 651, 653, the acquired measurement signals may optionally be pretreated, for example by filtering.

In step 208, an assignment between test signals and measurement signals is determined. In other words, in step 208, the test signals are identified in the measurement signals. The individual test signals may be identified in the measurement signals by way of filters or a discrete Fourier transform for the fourth harmonics, as described above in conjunction with the example of FIG. 1.

Based on the assignment between test signals and measurement signals determined in step 208, it is easily possible to establish whether the expected test signals have been acquired at the corresponding test plugs 618, 619, 638 and 639. In the case of assignments that are not as expected, incorrect wiring may be established.

In step 210, polarities of the measurement signals that were acquired at the test plugs 618, 619, 638 and 639 are determined. The polarity is detected based on the waveform that is asymmetric in the time domain, as described above with reference to the electrical installation 150 from FIG. 1.

In step 212, the circuit assignments and polarities determined in this way may be output, for example, on a display device for a user.

As an alternative or in addition, in step 214, the detected circuit assignments may be compared with target assignments and/or the detected polarities may be compared with target polarities. A warning may be output automatically if a deviation between the detected state and the target state has been established.

In summary, the different test signals described above enable a quick and reliable check of the wiring of the electrical installation. The test signals have a waveform that is asymmetric in the time domain and a combination of predefined harmonics having at least one higher harmonic, wherein the amplitude and/or phase of the at least one higher harmonic of the multiple test signals are different. Since the test signals are free from DC current, no saturation effects occur in transformers or capacitances, for example, such that the test signals are able to be transmitted via converters without any problems. Moreover, the test signals allow detection of polarity errors and unambiguous distinction of the individual phases. The threshold values, which are used here to identify the higher harmonics, may be selected so as to be relative with respect to the fundamental, and are thus not dependent on the absolute amplitude of the signals. The method therefore also works with partial signals, which may occur for example due to current division or in the case of undesirable ground connections.

The individual different test signals, and also linear combinations thereof, have the same asymmetric properties in the time domain and are therefore able to be assigned reliably to a polarity.

Using additional harmonics and/or additional different amplitudes makes it possible to distinguish between more than three phases. This makes it possible for example to distinguish simultaneously between further phases, for example in 2×3 phase systems, or to use coding with a Hamming distance greater than one in order to improve robustness to amplitude errors.

1. A method for testing wiring of an electrical installation having multiple circuits, comprising:
generating multiple test signals, wherein each of the multiple test signals has a combination of predefined harmonics having at least one higher harmonic, wherein the amplitude and/or phase of the at least one higher harmonic of the multiple test signals are different, and
injecting the multiple test signals into multiple first connections, which are assigned to the multiple circuits, at a first point of the electrical installation, wherein a different test signal of the multiple test signals is injected into each first connection of the multiple first connections.

2. The method according to claim 1, wherein the multiple test signals are injected simultaneously into the multiple first connections.

3. The method according to claim 1, wherein the at least one higher harmonic comprises fourth and/or fifth harmonics.

4. The method according to claim 1, wherein the combination or predefined harmonics comprises, in addition to a fundamental, at least one of a second harmonic and a third harmonic.

5. The method according to claim 1, wherein a fundamental of the predefined harmonics has a frequency different from a mains frequency of the electrical installation.

6. The method according to claim 1, wherein a fundamental of the predefined harmonics has one of a frequency in the range of 50 to 60 Hz, a frequency in the range of 51 to 55 Hz, and a frequency of 52.6 Hz.

7. The method according to claim 1, wherein the at least one higher harmonic comprises fourth and fifth harmonics, wherein the fourth harmonic has an amplitude factor of 1.35/16 or 1/16 or 0.65/16, and the fifth harmonic has an amplitude factor of 1.5/25 or 1/25 or 0.5/25 relative to an amplitude of a fundamental of the predefined harmonics, wherein an amplitude of one of the other nth higher harmonics of the predefined harmonics has an amplitude factor of 1/n² relative to an amplitude of the fundamental of the predefined harmonics.

8. The method according to claim 1, wherein the at least one higher harmonic comprises fourth and fifth harmonics, wherein the fourth harmonic has a phase offset of +30° or 0° or −30°, and the fifth harmonic has a phase offset of +30° or 0° or −30° relative to a phase of a fundamental of the predefined harmonics.

9. The method according to claim 1, further comprising:
acquiring multiple measurement signals at multiple second connections, which are assigned to the multiple circuits, at a second point of the electrical installation.

10. The method according to claim 9, further comprising:
determining assignments between in each case a first connection of the multiple first connections and a second connection of the multiple second connections on the basis of the injected test signals and the acquired measurement signals.

11. The method according to claim 10, wherein determining assignments comprises:
determining amplitudes and phases of spectral components for frequencies of the predefined harmonics in the measurement signals, and
comparing the amplitudes and phases of the spectral components with amplitude threshold values or phase threshold values.

12. The method according to claim 11, wherein the amplitude threshold values are set on the basis of an amplitude of a fundamental of the predefined harmonics.

13. The method according to claim 10, further comprising one or both of:
outputting the assignments between in each case a first connection of the multiple first connections and a second connection of the multiple second connections to a user, and
comparing the assignments between in each case a first connection of the multiple first connections and a second connection of the multiple second connections with predefined assignments between in each case a first connection of the multiple first connections and a second connection of the multiple second connections.

14. The method according to claim 1, wherein each of the multiple test signals has a waveform that is asymmetric in the time domain.

15. The method according to claim 9, wherein each of the multiple test signals has a waveform that is asymmetric in the time domain, further comprising:
determining polarities of the acquired measurement signals in order to test the wiring of the electrical installation depending on the determined polarities.

16. The method according to claim 15, wherein determining polarities of the acquired measurement signals for a respective measurement signal of the acquired measurement signals comprises:
determining a derivative of a respective measurement signal,
generating a comparison signal by comparing the derivative with a threshold value,
determining an average of the comparison signal, and
determining the polarity of the respective measurement signal on the basis of the average of the comparison signal.

17. The method according to claim 15, wherein determining polarities of the acquired measurement signals for a respective measurement signal of the acquired measurement signals comprises:
determining a correlation factor on the basis of a respective measurement signal and the waveform that is asymmetric in the time domain, and
determining the polarity of the respective measurement signal on the basis of the correlation factor.

18. A test device for testing wiring of an electrical installation having multiple circuits, comprising:
a test signal generation device that is configured to generate multiple test signals, wherein each of the multiple test signals has a combination of predefined harmonics having at least one higher harmonic, wherein the amplitude and/or phase of the at least one higher harmonic of the multiple test signals are different, and
an injection device that is configured to inject the multiple test signals into multiple first connections, which are assigned to the multiple circuits, at a first point of the electrical installation, wherein a different test signal of the multiple test signals is injected into each first connection of the multiple first connections.

19. The test device according to claim 18, further comprising:
an acquisition device that is configured to acquire multiple measurement signals at multiple second connections, which are assigned to the multiple circuits, at a second point of the electrical installation.

20. The test device according to claim 19, further comprising:
a processing device that is configured to determine assignments between in each case a first connection of the multiple first connections and a second connection of the multiple second connections on the basis of the injected test signals and the acquired measurement signals.

21. The test device according to claim 20, wherein the processing device is configured to acquire multiple measurement signals at multiple second connections, which are assigned to the multiple circuits, at a second point of the electrical installation.

22. The test device according to claim 21, wherein the processing device is configured to determine assignments between in each case a first connection of the multiple first connections and a second connection of the multiple second connections on the basis of the injected test signals and the acquired measurement signals.
